(19) United States
(12) Patent Application Publication
(10) Pub. No.: US 2025/0218845 A1
(43) Pub. Date: Jul. 3, 2025

(54) SAMPLE HOLDER

(71) Applicant: KYOCERA Corporation, Kyoto-shi, Kyoto (JP)

(72) Inventor: Tomoya TAKASAKI, Kirishima-shi (JP)

(73) Assignee: KYOCERA Corporation, Kyoto-shi, Kyoto (JP)

(21) Appl. No.: 18/851,442

(22) PCT Filed: Mar. 22, 2023
(86) PCT No.: PCT/JP2023/011337

§ 371 Date: Sep. 26, 2024

(30) Foreign Application Priority Data
Mar. 29, 2022 (JP) 2022-054579

(51) Int. Cl. H01L 21/683; H01J 37/32

(52) U.S. Cl. CPC H01L 21/6833; H01J 37/32715; H01J 2237/2007

(57) ABSTRACT

A sample holder includes a ceramic plate, a heat-resistant member, and a base member. The ceramic plate, the heat-resistant member, and the base member are located in this order. The heat-resistant member has a coefficient of thermal expansion smaller than that of the ceramic plate, and is not bonded to the ceramic plate.

### CROSS-REFERENCE TO RELATED APPLICATIONS

This application is a national stage application of International Application No. PCT/JP2023/011337, filed on Mar. 22, 2023, which designates the United States, the entire contents of which are herein incorporated by reference, and which is based upon and claims the benefit of priority to Japanese Patent Application No. 2022-054579, filed on Mar. 29, 2022, the entire contents of which are herein incorporated by reference.

### TECHNICAL FIELD

An embodiment of the disclosure relates to a sample holder.

### BACKGROUND OF INVENTION

There is a sample holder holding a sample such as a semiconductor wafer to be subjected to plasma treatment. Such a sample holder is configured by bonding a ceramic plate having a sample holding surface to a cooling member made of a metal.

As the sample holder, a structure is proposed in which a composite material having a coefficient of thermal expansion relatively close to a coefficient of thermal expansion of a ceramic plate is disposed between the ceramic plate and the cooling member, the composite material and the cooling member are bonded to each other with an adhesive, and the composite material and the ceramic plate are bonded to each other with a metal (see, for example, Patent Document 1).

### CITATION LIST

### Patent Literature

Patent Document 1: JP 2017-126640 A

### SUMMARY

A sample holder according to an aspect of an embodiment includes a ceramic plate, a heat-resistant member, and a base member. The ceramic plate, the heat-resistant member, and the base member are located in this order. The heat-resistant member has a coefficient of thermal expansion smaller than that of the ceramic plate, and is not bonded to the ceramic plate.

### BRIEF DESCRIPTION OF THE DRAWINGS

FIG. 1 is a perspective view schematically illustrating a configuration of a sample holder according to an embodiment.

FIG. 2 is a cross-sectional view schematically illustrating the sample holder illustrated in FIG. 1.

FIG. 3 is a cross-sectional view schematically illustrating the sample holder according to another embodiment 1.

FIG. 4 is a cross-sectional view schematically illustrating the sample holder according to another embodiment 2.

FIG. 5 is an enlarged view of a region A illustrated in FIG. 4.

FIG. 6 is a view illustrating an example of an appearance configuration of each protruding portion illustrated in FIG. 5.

FIG. 7 is a view illustrating another example of the appearance configuration of each protruding portion illustrated in FIG. 5.

FIG. 8 is a cross-sectional view schematically illustrating the sample holder according to another embodiment 3.

FIG. 9 is a cross-sectional view schematically illustrating the sample holder according to another embodiment 4.

FIG. 10 is a view illustrating an example of a coating aspect by a coating layer according to another embodiment 4.

FIG. 11 is a view illustrating another example of the coating aspect by the coating layer according to another embodiment 4.

FIG. 12 is a cross-sectional view schematically illustrating the sample holder according to another embodiment 5.

FIG. 13 is a plane perspective view of a ceramic plate illustrated in FIG. 12, as viewed from a second surface side.

### DESCRIPTION OF EMBODIMENTS

Hereinafter, an embodiment of a sample holder disclosed in the present disclosure will be described with reference to the accompanying drawings. The present disclosure is not limited by the following embodiments. Note that the drawings are schematic and that the dimensional relationships between elements, the proportions of the elements, and the like may differ from the actual ones. There may be differences between the drawings in terms of dimensional relationships, proportions, and the like.

In the embodiments described below, expressions such as “constant”, “orthogonal”, “perpendicular”, and “parallel” may be used, but these expressions do not mean exactly “constant”, “orthogonal”, “perpendicular”, and “parallel”. In other words, it is assumed that the above expressions allow for deviations in manufacturing accuracy, installation accuracy, or the like.

### Embodiment

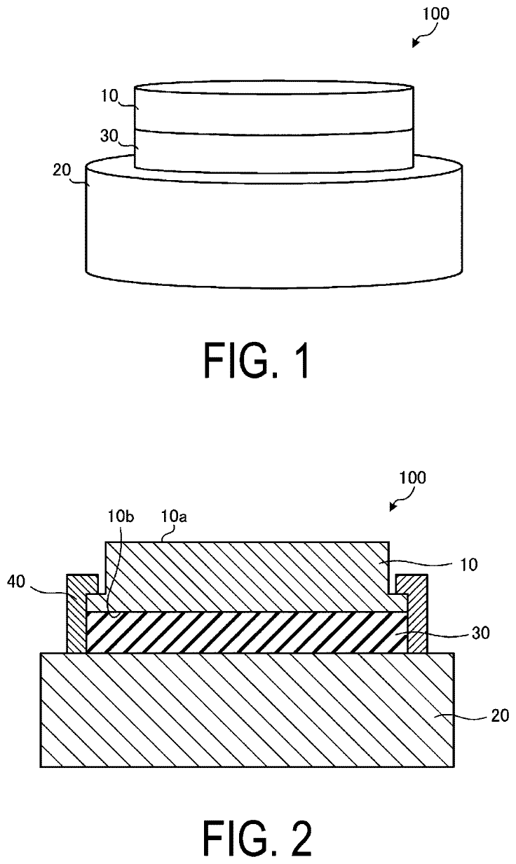

FIG. 1 is a perspective view schematically illustrating a configuration of a sample holder according to an embodiment. FIG. 2 is a cross-sectional view schematically illustrating the sample holder illustrated in FIG. 1.

As illustrated in FIGS. 1 and 2, a sample holder 100 includes a ceramic plate 10, a base member 20, and a heat-resistant member 30.

The ceramic plate 10 is a member obtained by molding and firing a raw material containing ceramic into a substantially disk shape. The ceramic plate 10 adsorbs and holds a sample such as a semiconductor wafer by using an electrostatic force. The ceramic plate 10 contains, for example, aluminum oxide (Al₂O₃), aluminum nitride (AlN), or yttria (Y₂O₃) as a main component.

The ceramic plate 10 has a first surface 10a and a second surface 10b located on an opposite side to the first surface 10a. The sample such as the semiconductor wafer is held on the first surface 10a. That is, the first surface 10a serves as a sample holding surface holding the sample.

An electrostatic adsorption electrode is located at an inner portion of the ceramic plate 10. The ceramic plate 10 may incorporate, for example, a heater electrode heating the ceramic plate 10. As a material of these electrodes, for example, a metal such as platinum, tungsten, molybdenum or the like can be used.

The ceramic plate 10 is fixed to the base member 20 via a fixing member 40. In FIG. 1, the fixing member 40 is not illustrated for convenience of explanation. As the fixing member 40, for example, a bolt and a clamp can be used. The ceramic plate 10 may be fixed to the base member 20 by other mechanical means instead of the fixing member 40.

The base member 20 is located on the second surface 10b side of the ceramic plate 10, that is, on the side opposite to the ceramic plate 10 with the heat-resistant member 30 interposed therebetween. The base member 20 is a support member supporting the ceramic plate 10 (and the heat-resistant member 30). The base member 20 is attached to, for example, a semiconductor manufacturing device, and causes the sample holder 100 to function as a semiconductor holding device holding the sample such as the semiconductor wafer.

The base member 20 is a substantially cylindrical member. The material of the base member 20 may be, for example, a metal such as aluminum, titanium, stainless steel, or the like, or a composite material of a ceramic such as silicon carbide or the like and a metal such as aluminum or the like. In this case, the base member 20 may also serve as, for example, a high-frequency electrode.

The base member 20 functions as a cooling member for cooling the ceramic plate 10 heated by the plasma treatment on the sample. The base member 20 may be, for example, a heat exchanger. In such a case, the base member 20 may include a channel through which a heat exchange medium such as a liquid or a gas flows.

The heat-resistant member 30 is located between the ceramic plate 10 and the base member 20. The heat-resistant member 30 has heat-resistant and a coefficient of thermal expansion smaller than that of the ceramic plate 10. The coefficient of thermal expansion of the heat-resistant member 30 is smaller than the coefficient of thermal expansion of the ceramic plate 10, and thus even when the heat-resistant member 30 is heated to, for example, 300°° C. or more, the heat-resistant member 30 can reduce deformation due to a temperature difference in the thickness direction of the heat-resistant member 30. The heat-resistant member 30 may be made of, for example, cordierite or glass.

The heat-resistant member 30 is located between the ceramic plate 10 and the base member 20 in a state where the heat-resistant member 30 is not bonded to the ceramic plate 10.

When the heat-resistant member 30 and the ceramic plate 10 are bonded to each other with a bonding material or the like, warpage of the heat-resistant member 30 and the ceramic plate 10 may occur due to the difference in thermal expansion between the heat-resistant member 30 and the ceramic plate 10. When the warpage occurs due to the difference in thermal expansion between the heat-resistant member 30 and the ceramic plate 10, heat transfer between the heat-resistant member 30 and the base member 20 becomes non-uniform, heat transfer between the first surface 10a, that is, the sample holding surface of the ceramic plate 10 and the base member 20 becomes non-uniform in an in-plane direction, and in-plane thermal uniformity of the sample holder 100 is impaired.

On the other hand, the heat-resistant member 30 having the coefficient of thermal expansion smaller than that of the ceramic plate 10 is not bonded to the ceramic plate 10, and thus the heat-resistant member 30 and the ceramic plate 10 easily slide against each other as compared with the case where the heat-resistant member 30 and the ceramic plate 10 are bonded to each other, and the warpage due to the difference in thermal expansion between the heat-resistant member 30 and the ceramic plate 10 can be reduced. As a result, non-uniformity of heat transfer between the heat-resistant member 30 and the base member 20 can be reduced, and thus non-uniformity of heat transfer between the sample holding surface and the base member 20 in the in-plane direction can be reduced. Thus, the in-plane thermal uniformity of the sample holder 100 can be improved.

The ceramic plate 10 is fixed to the base member 20 via the fixing member 40, and thus the heat-resistant member 30 is located interposed between the ceramic plate 10 and the fixing member 40. The heat-resistant member 30 is interposed between the ceramic plate 10 and the fixing member 40, and thus the position of the heat-resistant member 30 can be fixed even when the heat-resistant member 30 is not bonded to the ceramic plate 10 and the base member 20.

### Another Embodiment

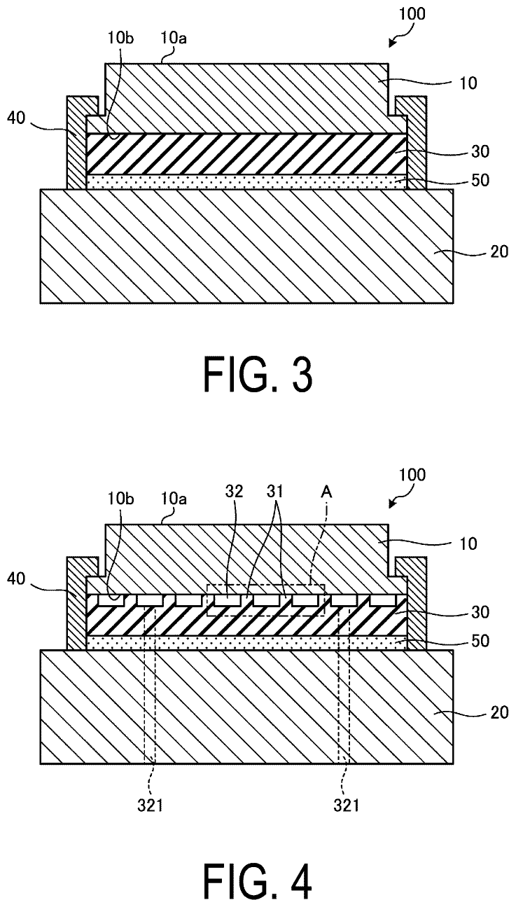

FIG. 3 is a cross-sectional view schematically illustrating the sample holder according to another embodiment 1. The sample holder 100 illustrated in FIG. 3 further includes a bonding material 50.

The bonding material 50 is located between the heat-resistant member 30 and the base member 20. The bonding material 50 bonds the heat-resistant member 30 and the base member 20 to each other. The heat-resistant member 30 and the base member 20 are bonded to each other by the bonding material 50, the warpage of the heat-resistant member 30 due to a thermal cycle can be reduced as compared with the case where the heat-resistant member 30 and the base member 20 are not bonded to each other. As a result, the non-uniformity of heat transfer between the ceramic plate 10 and the heat-resistant member 30 can be reduced, and thus the non-uniformity of heat transfer between the sample holding surface and the base member 20 in the in-plane direction can be further reduced. Thus, the in-plane thermal uniformity of the sample holder 100 can be further improved.

The heat-resistant member 30 and the base member 20 are bonded to each other by the bonding material 50, and thus a position shift between the heat-resistant member 30 and the base member 20 can be reduced.

The bonding material 50 may have a lower heat transfer coefficient than that of the heat-resistant member 30. As the bonding material 50, an adhesive such as a silicone resin or the like can be used. When the heat transfer coefficient of the bonding material 50 is small, the bonding material 50 functions as a heat insulating layer, and thus the temperature difference between a surface of the heat-resistant member 30 on the ceramic plate 10 side and a surface of the heat-resistant member 30 on the bonding material 50 side can be reduced, and the warpage of the heat-resistant member 30 due to the temperature difference in the thickness direction of the heat-resistant member 30 can be further reduced.

FIG. 4 is a cross-sectional view schematically illustrating the sample holder according to another embodiment 2. In the sample holder 100 illustrated in FIG. 4, the surface of the heat-resistant member 30 on the ceramic plate 10 side includes a plurality of protruding portions 31 (an example of first protruding portions) each in contact with the ceramic plate 10 and spaces 32 (an example of a first space) located around each protruding portion 31. The plurality of protruding portions 31 and the spaces 32 can be formed by, for example, blasting the surface of the heat-resistant member 30 on the ceramic plate 10 side. The heat-resistant member 30 includes the plurality of protruding portions 31 and the spaces 32, and thus a contact area between the heat-resistant member 30 and the ceramic plate 10 can be reduced. As a result, the ceramic plate 10 easily slides against the heat-resistant member 30, and the stress generated by an expansion/contraction difference between the heat-resistant member 30 and the ceramic plate 10 due to the thermal cycle can be relaxed.

The space 32 is located around each protruding portion 31 and between the ceramic plate 10 and the heat-resistant member 30. The space 32 has a depth corresponding to the height of each protruding portion 31. A heat transfer gas such as helium may be introduced into the space 32. That is, the space 32 may be a channel of the heat transfer gas. In this case, for example, the heat transfer gas may be introduced into the space 32 from a gas supply mechanism (not illustrated) through a gas introduction hole 321. The gas introduction hole 321 penetrates the base member 20, the bonding material 50, and the heat-resistant member 30 and communicates with the space 32. The heat transfer gas is introduced into the space 32, and thus the heat transfer gas can be fed to the second surface 10b of the ceramic plate 10, and heat transfer between the heat-resistant member 30 and the ceramic plate 10 via the space 32 is improved.

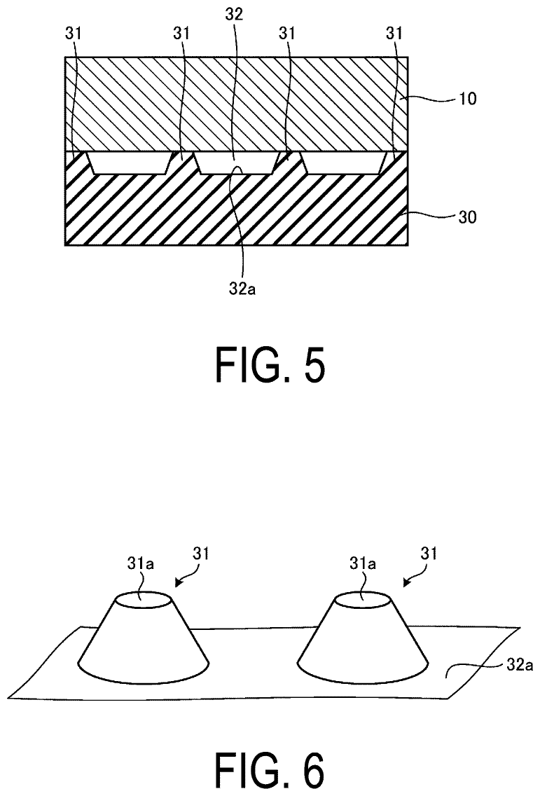

Here, a detail of each protruding portion 31 will be further described with reference to FIGS. 5 and 6. FIG. 5 is an enlarged view of a region A illustrated in FIG. 4. FIG. 6 is a view illustrating an example of an appearance configuration of each protruding portion illustrated in FIG. 5.

As illustrated in FIGS. 5 and 6, the side surface of each protruding portion 31 may have a tapered shape with a width being narrowed toward the ceramic plate 10. In other words, each protruding portion 31 may be formed in the tapered shape with a width being narrowed toward a top portion of each protruding portion 31. Each protruding portion 31 is formed in the tapered shape, and thus a surface area of an end surface 31a of each protruding portion 31 in contact with the ceramic plate 10 can be reduced, and the contact area between the heat-resistant member 30 and the ceramic plate 10 can be reduced. As a result, the ceramic plate 10 further easily slides against the heat-resistant member 30, and the stress generated by the expansion/contraction difference between the heat-resistant member 30 and the ceramic plate 10 due to the thermal cycle can be further relaxed.

A surface roughness Ra of the end surface 31a of each protruding portion 31 in contact with the ceramic plate 10 may be smaller than a surface roughness Ra of a bottom surface 32a of the space 32. As a result, the end surface 31a of each protruding portion 31 and the ceramic plate 10 can be brought into uniform contact with each other in the in-plane direction, and heat transfer from the ceramic plate 10 to the plurality of protruding portions 31 can be equalized. When the surface roughness Ra of the end surface 31a of each protruding portion 31 in contact with the ceramic plate 10 is small, the ceramic plate 10 further easily slides against the heat-resistant member 30, and the stress generated by the expansion/contraction difference between the heat-resistant member 30 and the ceramic plate 10 due to the thermal cycle can be further relaxed. When the surface roughness Ra of the bottom surface 32a of the space 32 is large, the surface area of the bottom surface 32a of the space 32 can be increased. As a result, for example, when the heat transfer gas is introduced into the space 32, heat exchange between the heat transfer gas and the heat-resistant member 30 can be promoted.

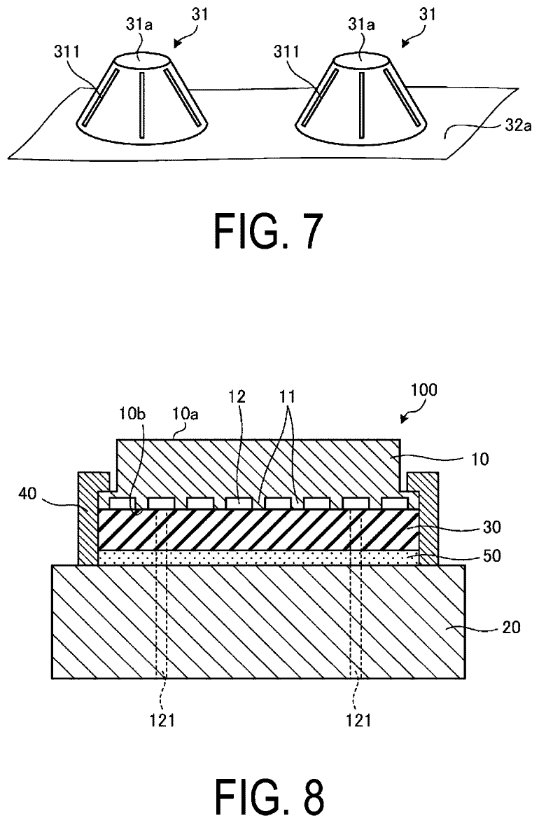

As illustrated in FIG. 7, the side surface of each protruding portion 31 may include grooves 311. FIG. 7 is a view illustrating another example of the appearance configuration of each protruding portion illustrated in FIG. 5. The flow of the heat transfer gas introduced into the space 32 can be disturbed by providing the grooves 311 on the side surface of each protruding portion 31, the heat exchange between the heat transfer gas and the heat-resistant member 30 can be promoted.

The grooves 311 may extend on the side surface of each protruding portion 31 in a direction from the end surface 31a of each protruding portion 31 in contact with the ceramic plate 10 toward the bottom surface 32a of the space 32. As a result, the flow direction of the heat transfer gas introduced into space 32 and the extending direction of the groove 311 intersect with each other, and thus the flow of the heat transfer gas can be efficiently disturbed, and the heat exchange between the heat transfer gas and heat-resistant member 30 can be further promoted.

Note that the extending direction of the grooves 311 is not limited to the direction illustrated in FIG. 7. The grooves 311 may extend in any direction on the side surface of each protruding portion 31.

In the example illustrated in FIG. 7, the case is illustrated in which the grooves 311 are provided on the side surface of each protruding portion 31, but instead of the grooves 311, protrusions may be provided on the side surface of each protruding portion 31. Both the grooves 311 and the protrusions may be provided on the side surface of each protruding portion 31.

FIG. 8 is a cross-sectional view schematically illustrating the sample holder according to another embodiment 3. The sample holder 100 illustrated in FIG. 8 includes, on a surface of the ceramic plate 10 on the heat-resistant member 30 side, that is, on the second surface 10b, a plurality of protruding portions 11 (an example of second protruding portions) each in contact with the heat-resistant member 30 and spaces 12 (an example of a second space) located around each protruding portion 11. The plurality of protruding portions 11 and the spaces 12 can be formed by, for example, blasting the second surface 10b of the ceramic plate 10. The ceramic plate 10 includes the plurality of protruding portions 11 and the spaces 12, and thus the contact area between the heat-resistant member 30 and the ceramic plate 10 can be reduced. As a result, the ceramic plate 10 easily slides against the heat-resistant member 30, and the stress generated by an expansion/contraction difference between the heat-resistant member 30 and the ceramic plate 10 due to the thermal cycle can be relaxed.

Each protruding portion 11 may be formed in a tapered shape as in each protruding portion 31 illustrated in FIGS. 5 and 6. A surface roughness Ra of the end surface of each protruding portion 11 in contact with the heat-resistant member 30 may be smaller than a surface roughness Ra of the bottom surface of the space 12. Each protruding portion 11 may include at least one of a protrusion and a groove on the side surface.

The space 12 is located around each protruding portion 11 and between the ceramic plate 10 and the heat-resistant member 30. The space 12 has a depth corresponding to the height of each protruding portion 11. A heat transfer gas such as helium may be introduced into the space 12. That is, the space 12 may be a channel of the heat transfer gas. In this case, for example, the heat transfer gas may be introduced into the space 12 from a gas supply mechanism (not illustrated) through a gas introduction hole 121. The gas introduction hole 121 penetrates the base member 20, the bonding material 50, and the heat-resistant member 30 and communicates with the space 12. The heat transfer gas is introduced into the space 12, and thus the heat transfer gas can be fed to the second surface 10b of the ceramic plate 10, and heat transfer between the heat-resistant member 30 and the ceramic plate 10 via the space 32 is improved.

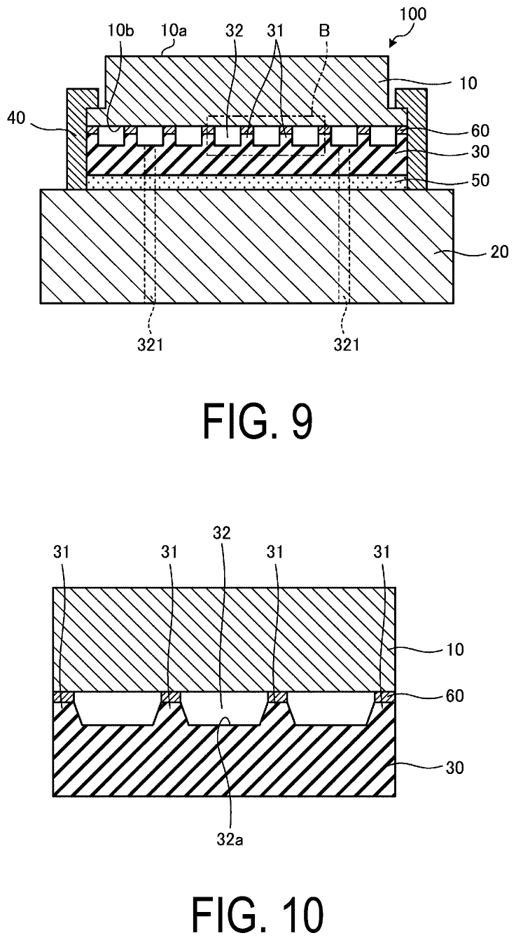

FIG. 9 is a cross-sectional view schematically illustrating the sample holder according to another embodiment 4. The sample holder 100 illustrated in FIG. 9 further includes a coating layer 60 (an example of a first intermediate layer, a second intermediate layer, and a third intermediate layer).

The coating layer 60 is located between the heat-resistant member 30 and the ceramic plate 10. The coating layer 60 covers the surface of the heat-resistant member 30 on the ceramic plate 10 side.

The coating layer 60 may have a friction coefficient smaller than that of the heat-resistant member 30. The coating layer 60 may have a hardness higher than that of the heat-resistant member 30. The coating layer 60 may have an electrical resistance lower than that of the ceramic plate 10. As the coating layer 60, for example, diamond-like carbon (DLC) or SiC may be used. When the friction coefficient of the coating layer 60 is small, a frictional force acting on the heat-resistant member 30 and the ceramic plate 10 due to the difference in thermal expansion between the heat-resistant member 30 and the ceramic plate 10 is reduced, and generation of particles from the heat-resistant member 30 and the ceramic plate 10 can be reduced. When the hardness of the coating layer 60 is high, even when the frictional force acts on the heat-resistant member 30 due to the difference in thermal expansion between the heat-resistant member 30 and the ceramic plate 10, wear of the heat-resistant member 30 is reduced, and the generation of particles from the heat-resistant member 30 can be reduced. When the electrical resistance of the coating layer 60 is small, electric charges remaining on the first surface 10a, that is, the sample holding surface of the ceramic plate 10 can be released to the coating layer 60, and thus the deterioration of the detachability of the sample due to the remaining electric charges in the ceramic plate 10 can be reduced. The coating layer 60 may have an electrical resistance lower than that of the heat-resistant member 30. As a result, the electric charges remaining on the sample holding surface can be further easily released.

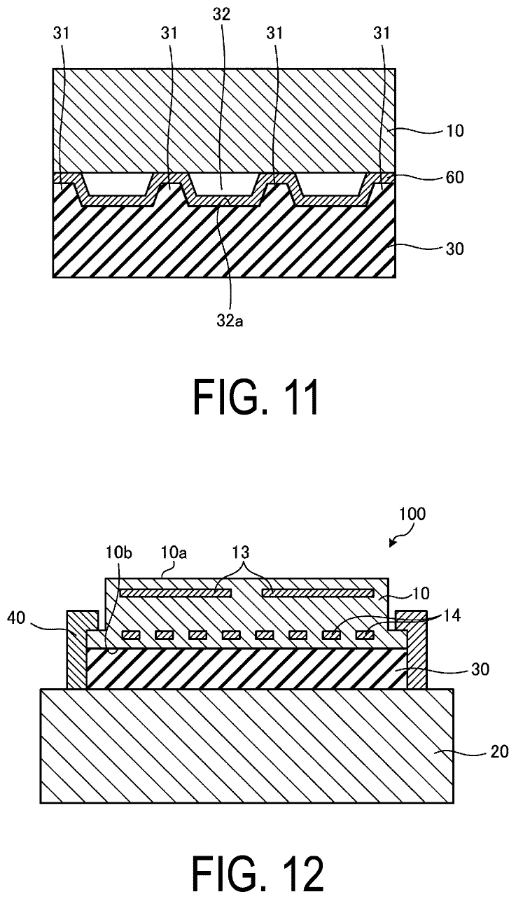

Here, details of the coating layer 60 will be further described with reference to FIGS. 10 and 11. FIG. 10 is a view illustrating an example of a coating aspect by a coating layer according to another embodiment 4. FIG. 11 is a view illustrating another example of the coating aspect by the coating layer according to another embodiment 4. FIGS. 10 and 11 correspond to enlarged views of a region B illustrated in FIG. 9.

As illustrated in FIG. 10, the coating layer 60 may be located to cover only the end surface 3 la (see FIG. 6) of each protruding portion 31 in contact with the ceramic plate 10. As a result, for example, when the heat transfer gas is introduced into the space 32, a decrease in a channel cross-sectional area of the space 32 serving as the channel of the heat transfer gas can be reduced.

As illustrated in FIG. 11, the coating layer 60 may be located to cover the end surface 31a (see FIG. 6) of each protruding portion 31 in contact with the ceramic plate 10, the side surface of each protruding portion 31, and the bottom surface 32a of the space 32. As a result, the coating layer 60 can cover the entire surface of the heat-resistant member 30 on the ceramic plate 10 side, and thus the electric charges remaining on the first surface 10a, that is, the sample holding surface of the ceramic plate 10 can be easily released to the coating layer 60.

FIG. 12 is a cross-sectional view schematically illustrating the sample holder according to another embodiment 5. As illustrated in FIG. 12, two first electrodes 13 and 13, which are electrostatic adsorption electrodes adsorbing and holding the sample such as the semiconductor wafer, may be located at an inner portion of the ceramic plate 10 on the first surface 10a side. Two second electrodes 14 and 14, which are electrostatic adsorption electrodes adsorbing and holding the heat-resistant member 30, may be located at an inner portion of the ceramic plate 10 on the second surface 10b side.

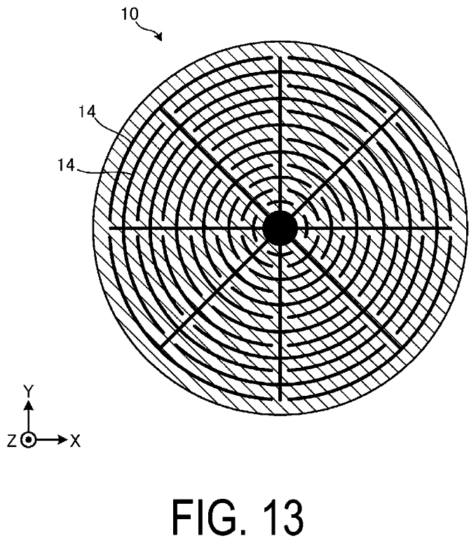

FIG. 13 is a plane perspective view of the ceramic plate 10 illustrated in FIG. 12, as viewed from the second surface 10b side. As illustrated in FIG. 13, the second electrodes 14 and 14 are, for example, comb-shaped electrodes in which one of the second electrodes 14 and the other one of the second electrodes 14 are alternately and finely arranged. The second electrodes 14 and 14 having such a shape can adsorb and hold not only a conductor and a semiconductor but also an insulator by a gradient force generated by applying a positive voltage to one of the second electrodes 14 and by applying a negative voltage to the other of the second electrodes 14. The heat-resistant member 30 is adsorbed and held on the ceramic plate 10 by the second electrodes 14 and 14 of the electrostatic adsorption electrode. The ceramic plate 10 is adsorbed and held by the heat-resistant member 30 and is fixed to the base member 20 via the fixing member 40.

The ceramic plate 10 is entirely adsorbed to the heat-resistant member 30, including the center portion, and thus deformation of the first surface 10a, which is the sample holding surface, is reduced, and a decrease in in-plane temperature homogeneity of the sample holding surface is less likely to occur. The deformation of the first surface 10a, which is the sample holding surface, is reduced as compared with the case where the outer peripheral portion of the ceramic plate 10 is only mechanically fixed, and thus peeling of the sample from the sample holding surface and reduction in processing accuracy of the sample are also less likely to occur. As described above, the sample holder 100 according to another embodiment 5 can withstand use in a high-temperature environment while reducing the deformation of the sample holding surface.

Further effects and variations can be readily derived by those skilled in the art. Thus, a wide variety of aspects of the present invention are not limited to the specific details and representative embodiments represented and described above. Accordingly, various changes can be made without departing from the spirit or scope of the general inventive concepts defined by the appended claims and their equivalents.

### REFERENCE SIGNS

10 Ceramic plate
10a First surface
10b Second surface
11 Protruding portion
12 Space
13 First electrode
14 Second electrode
20 Base member
30 Heat-resistant member
31 Protruding portion
31a End surface
32 Space
32a Bottom surface
40 Fixing member
50 Bonding material
60 Coating layer
100 Sample holder
311 Groove

1. A sample holder comprising:
a ceramic plate;
a heat-resistant member; and
a base member, wherein
the ceramic plate, the heat-resistant member, and the base member are located in this order, and
the heat-resistant member has a coefficient of thermal expansion smaller than a coefficient of thermal expansion of the ceramic plate, and is not bonded to the ceramic plate.

2. The sample holder according to claim 1, further comprising a fixing member configured to fix the ceramic plate.

3. The sample holder according to claim 1, further comprising a bonding material located between the heat-resistant member and the base member.

4. The sample holder according to claim 1, wherein the heat-resistant member comprises a plurality of first protruding portions being in contact with the ceramic plate and a first space located around each of the plurality of first protruding portions.

5. The sample holder according to claim 4, wherein a side surface of the first protruding portion has a tapered shape with a width being narrowed toward the ceramic plate.

6. The sample holder according to claim 4, wherein a surface roughness of an end surface, being in contact with the ceramic plate, of the first protruding portion is smaller than a surface roughness of a bottom surface of the first space.

7. The sample holder according to claim 4, wherein a heat transfer gas is introduced into the first space.

8. The sample holder according to claim 5, wherein the side surface of the first protruding portion comprises a protrusion and/or a groove.

9. The sample holder according to claim 8, wherein the protrusion and/or the groove extends in a direction from an end surface, being in contact with the ceramic plate, of the first protruding portion toward a bottom surface of the first space.

10. The sample holder according to claim 1, wherein the ceramic plate comprises a plurality of second protruding portions being in contact with the heat-resistant member and a second space located around each of the plurality of second protruding portions.

11. The sample holder according to claim 10, wherein a heat transfer gas is introduced into the second space.

12. The sample holder according to claim 1, further comprising a first intermediate layer between the heat-resistant member and the ceramic plate, wherein
the first intermediate layer has a friction coefficient smaller than a friction coefficient of the heat-resistant member.

13. The sample holder according to claim 1, further comprising a second intermediate layer between the heat-resistant member and the ceramic plate, wherein
the second intermediate layer has a hardness higher than a hardness of the heat-resistant member.

14. The sample holder according to claim 1, further comprising a third intermediate layer between the heat-resistant member and the ceramic plate, wherein
the third intermediate layer has an electrical resistance smaller than an electrical resistance of the ceramic plate.

15. The sample holder according to claim 1, wherein
the ceramic plate comprises an electrostatic adsorption electrode at an inner portion of the ceramic plate, and
the heat-resistant member is adsorbed to the ceramic plate by the electrostatic adsorption electrode.
